(19) United States
(12) Patent Application Publication
(10) Pub. No.: US 2011/0068397 A1
(43) Pub. Date: Mar. 24, 2011

(54) POWER DEVICES AND ASSOCIATED METHODS OF MANUFACTURING

(76) Inventor: Donald R. Disney, Cupertino, CA (US)

(21) Appl. No.: 12/566,575

(22) Filed: Sep. 24, 2009

(51) Int. Cl. H01L 29/78; H01L 21/20

(52) U.S. Cl. 257/341; 438/495; 257/E21.09; 257/E29.257

(57) ABSTRACT

Power devices and associated methods of manufacturing are disclosed herein. In one embodiment, a power device includes a drain at a first end, a source and a gate at a second end, and a drift region between the drain at the first end and the source at the second end. The drift region includes a p-type dopant column juxtaposed with an n-type dopant column. The p-type dopant column and the n-type dopant column together have a width less than 12 microns.

### TECHNICAL FIELD

The current technology is related generally to power devices and associated methods of manufacturing. In particular, the current technology is related generally to vertical metal-oxide field effect transistors (MOSFET) and associated methods of manufacturing.

### BACKGROUND

Vertical MOSFET generally have superior power switching performance when compared to conventional bipolar devices. However, the on-state resistance of power MOSFET increases sharply as breakdown voltage increases. As a result, vertical MOSFET may be unusable in high voltage applications.

One solution for achieving lower on-state resistance while maintaining reasonable breakdown voltage is by utilizing “super junctions.” FIG. 1 schematically illustrates a conventional n-type vertical MOSFET 10 with super junctions. As shown in FIG. 1, the MOSFET 10 includes a drain electrode 12 coupled to an n-type drain 13 at a first end 10a, a source electrode 14 coupled to an n-type source 20, and a gate 16 spaced apart from the drain 12 at a second end 10b, and a drift region 18 between the first and second ends 10a and 10b. The MOSFET 10 also includes a p-type well 21 proximate to the source 14 and the gate 16, forming the body region of the field effect transistor.

The drift region 18 includes a p-type pillar 22 juxtaposed with an n-type pillar 24, forming a “super junction.” The p-type pillar 22 and the n-type pillar 24 are doped with select ion concentrations such that these two pillars at least approximately deplete each other laterally. As a result, the MOSFET 10 may have a high breakdown voltage between the source 14 and the drain 12. In operation, the n-type pillar 24 forms a conduction channel between the drain 12 and the source 14. Compared with conventional power MOSFET, the n-type pillar 24 may be doped with higher concentrations and thus may have a low on-state resistance.

FIGS. 2A-2C are partially schematic cross-sectional views of a semiconductor substrate 11 undergoing a process for forming the vertical MOSFET 10 of FIG. 1 in accordance with the prior art. As shown in FIG. 2A, the process includes depositing an n-type epitaxial layer 26 and implanting a p-type dopant 28 (e.g., boron) on a surface 27 of the n-type epitaxial layer 26. As shown in FIG. 2B, the n-type epitaxial layer 26 deposition and p-type dopant 28 implantation operations are repeated to form a drift region 18 until a desired thickness is achieved. As shown in FIG. 2C, the implanted p-type dopant 28 is thermally diffused to merge into the p-type pillar 22.

Thermally diffusing and merging the p-type dopant 28 in the multiple n-type epitaxial layers 26, however, requires a long processing duration because the p-type dopant 28 is implanted superficially on the surface 27 of the n-type epitaxial layers 26. As a result, the p-type dopant 28 diffuses not only vertically but also laterally to a significant degree. As a result, the foregoing technique cannot form pillars with small lateral dimensions (e.g., less than 12 microns) except by using a large number (e.g., 20) of epitaxial layer depositions. Accordingly, certain improvements are needed for efficiently and cost effectively forming small dimension pillars in vertical MOSFET.

### BRIEF DESCRIPTION OF THE DRAWINGS

FIG. 1 is a partially schematic cross-sectional view of a vertical MOSFET in accordance with the prior art.

FIGS. 2A-2C are partially schematic cross-sectional views of a semiconductor substrate undergoing a process for forming the vertical MOSFET of FIG. 1 in accordance with the prior art.

FIGS. 3A-3G are partially schematic cross-sectional views of a semiconductor substrate undergoing a process for forming a vertical MOSFET in accordance with embodiments of the technology.

FIG. 4A illustrates an example of simulation results of the process in FIGS. 3A-3D.

FIG. 4B illustrates an example of simulation results of the process in FIG. 3E.

FIG. 4C is a plot of dopant concentration versus depth of the example of simulation results in FIG. 4B.

FIGS. 5A-5G are partially schematic cross-sectional views of a semiconductor substrate undergoing a process for forming a vertical MOSFET in accordance with additional embodiments of the technology.

### DETAILED DESCRIPTION

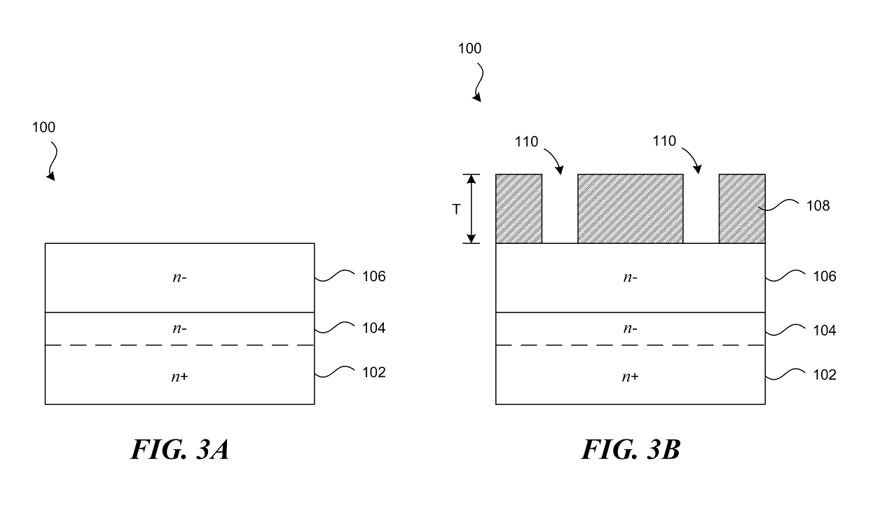

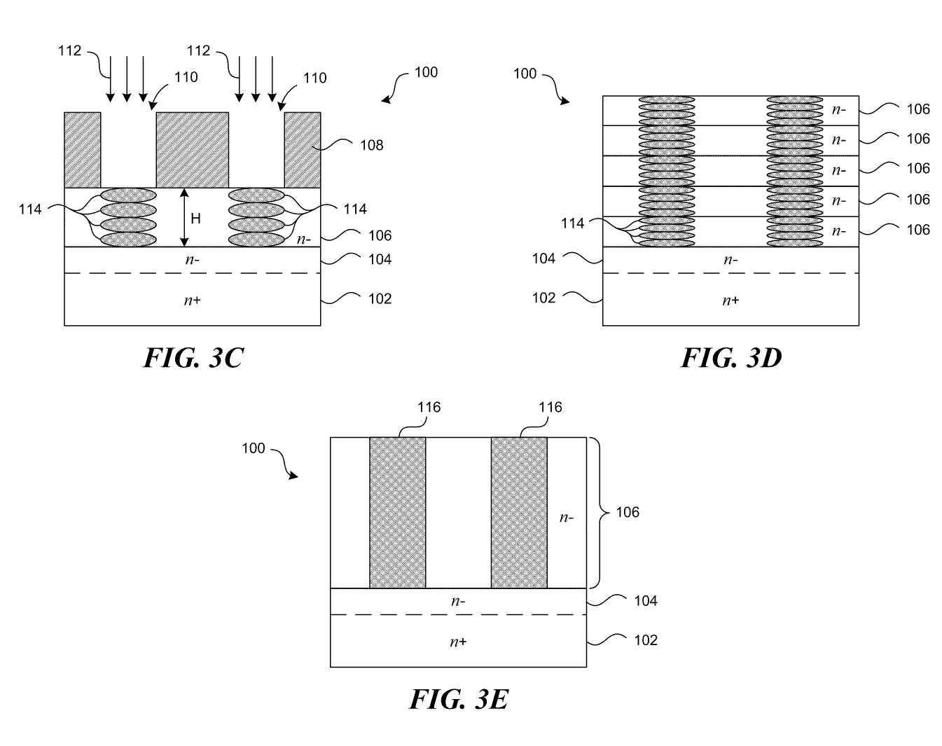

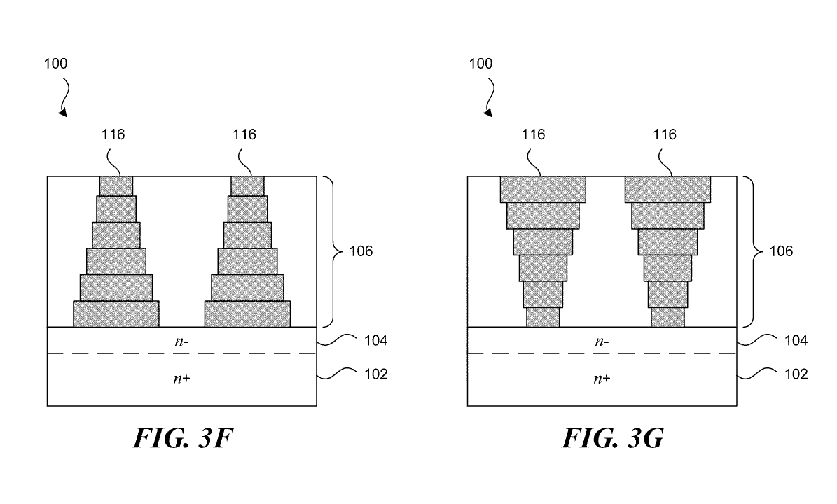

Several embodiments of the present technology are described below with reference to vertical MOSFET useful for power switching and associated methods of manufacturing. Many details of certain embodiments are described below with reference to semiconductor substrates. The term “semiconductor substrate” is used throughout to include a variety of articles of manufacture, including, for example, individual integrated circuit dies, sensor dies, switch dies, and/or dies having other semiconductor features. The term “photoresist” generally refers to a material that can be chemically modified when exposed to electromagnetic radiation. The term encompasses both positive photoresist, configured to be soluble when activated by the electromagnetic radiation, and negative photoresist, configured to be insoluble when activated by light. Many specific details of certain embodiments are set forth in FIGS. 3A-5G and in the following text to provide a thorough understanding of these embodiments. Several other embodiments can have configurations, components, and/or process operations different than those described in this disclosure. One of ordinary skill in the relevant art, therefore, will appreciate that additional embodiments may be practiced without several of the details of the embodiments shown in FIGS. 3A-5G.

FIGS. 3A-3G are partially schematic cross-sectional views of a semiconductor substrate 100 undergoing a process for forming a vertical MOSFET in accordance with embodiments of the technology. In the following discussion, the semiconductor substrate 100 includes an n-type substrate material for illustration purposes. One of ordinary skill in the art will understand that embodiments of the process may also include a p-type substrate material or an intrinsic (i.e., non-doped) substrate material in lieu of the n-type substrate material.

Referring to FIG. 3A, in the illustrated embodiment, the semiconductor substrate 100 includes a first n-type substrate material 102 and an optional second n-type substrate material 104. The first n-type substrate material has a first dopant concentration, and the optional second n-type substrate material 104 has a second dopant concentration lower than the first dopant concentration. In certain embodiments, the optional second n-type substrate material 104 may be deposited as an n-type epitaxial layer on the first n-type substrate material 102. In other embodiments, the first and second n-type substrate materials 102 and 104 may be formed via diffusion, implantation, and/or other suitable techniques. In further embodiments, the optional second n-type substrate material 104 may be omitted.

As shown in FIG. 3A, the process includes depositing an n-type epitaxial layer 106 onto the optional second substrate material 104 via chemical vapor deposition (CVD), plasma enhanced chemical vapor deposition (PECVD), atomic layer deposition (ALD), liquid phase epitaxy, and/or other suitable deposition techniques. The term “epitaxial layer” as used hereinafter generally refers to a monocrystalline film or layer on a monocrystalline substrate material. For example, the epitaxial layer 106 may include a monocrystalline silicon layer or other suitable semiconductor material doped with phosphorus (P), arsenic (As), antimony (Sb), and/or other suitable n-type dopant. In one embodiment, the epitaxial layer 106 has a dopant concentration that is generally the same as the optional second substrate material 104. In other embodiments, the epitaxial layer 106 may have other desired dopant concentrations. The epitaxial layer 106 may have a thickness of about 3 microns to about 5 microns and/or other desired thickness values.

After depositing the epitaxial layer 106, the process includes masking the epitaxial layer 106 with a masking material. In certain embodiments, masking the epitaxial layer 106 includes depositing a photoresist 108 (or other suitable masking materials) onto the epitaxial layer 106 via spin coating and/or other suitable techniques, as shown in FIG. 3B. In one embodiment, the photoresist 108 has a thickness T that is at least five microns. In other embodiments, the photoresist 108 may have other desired thicknesses based on, for example, characteristics of an implanted dopant, implantation conditions, and/or other suitable criteria.

The photoresist 108 may then be patterned to form openings 110 in the photoresist 108. The term “patterning” as used hereinafter generally refers to printing a desired pattern on a photoresist and subsequently removing certain portions of the photoresist to form the desired pattern in the photoresist using photolithography and/or other suitable techniques. Even though two openings 110 are shown in FIG. 3B, in certain embodiments, the photoresist 108 may include any desired number of openings 110 based at least on a desired number of pillars (or continuous dopant columns).

As shown in FIG. 3C, the process further includes implanting a plurality of vertically stacked dopant regions 114 into the epitaxial layer 106 via the openings 110. In the illustrated embodiment, four discrete dopant regions 114 are vertically stacked one on top of another and occupy the entire thickness H of the epitaxial layer 106. In other embodiments, any desired number of dopant regions 114 may be implanted in the epitaxial layer 106. In further embodiments, the implanted dopant regions 114 may be spaced apart from one another by a distance (e.g., 0.1 micron). In yet further embodiments, the implanted dopant regions 114 may occupy only a portion of the thickness H of the epitaxial layer 106. The individual dopant regions 114 can have a thickness of about 0.5 microns to about 1.5 microns and/or other desired thickness values.

In the illustrated embodiment, the individual dopant regions 114 may include the same dopant and generally the same dopant concentration and distribution profile. In other embodiments, the individual dopant regions 114 may include different dopants, dopant concentrations, and/or distribution profiles. For example, the dopant regions 114 may have graduated dopant concentrations and/or profiles from a first side to a second side of the epitaxial layer 106. In another example, different dopants may be used for at least some of the dopant regions 114.

In several embodiments, ion implantation techniques may be used for implanting the dopant regions 114. In such embodiments, the epitaxial layer 106 is bombarded with select dopant ions (as indicated by arrows 112). Suitable dopant ions may include boron (B), aluminum (Al), gallium (Ga), indium (In), thallium (Ti), and/or other suitable dopants. The depth, dopant concentration, and/or distribution profile of the individual dopant regions 114 may be controlled by altering or adjusting at least one of (1) an implantation energy, (2) an ion concentration, and (3) an implantation duration. For example, to implant a dopant region 114 with a low dopant concentration in a condensed profile deep into the epitaxial layer 106, a high implantation energy (e.g., greater than about 1,000 keV) with a low ion concentration and short implantation duration may be used. To implant a dopant region 114 with a high dopant concentration in a proliferated profile shallow into the epitaxial layer 106, low implantation energy (e.g., less than about 200 keV) with a high ion concentration and long implantation duration may be used. In other embodiments, implanting the dopant regions 114 may be via diffusion and/or other suitable techniques.

In certain embodiments, the thickness of the epitaxial layer 106 may be chosen based on the highest available ion implantation energy that can introduce an implanted dopant region 114 at a depth that allows the lowermost implanted region 114 in the epitaxial layer 106 to merge with the uppermost implanted region 114 of the same epitaxial layer 106. In other embodiments, the thickness of the epitaxial layer 106 may be chosen based on other suitable criteria.

In certain embodiments, an optional hardmask (e.g., silicon dioxide and/or other suitable masking materials, not shown) may be deposited on the epitaxial layer 106 before the photoresist 108 is deposited and patterned. Subsequently, the hardmask is etched through the openings in the photoresist before the ion implantation operation. The optional hardmask may provide improved masking of high-energy ion implantations with a thin layer, which may minimize the thickness of the photoresist 108 and may thus improve the manufacturability of the foregoing process.

As shown in FIG. 3D, the process includes removing the photoresist 108 and repeating the operation stages illustrated in FIGS. 3A-3C until a desired number of epitaxial layers 106 are formed. In the illustrated embodiment, five epitaxial layers 106 are shown for illustration purposes. In other embodiments, any desired number of epitaxial layers 106 may be formed on the first n-type substrate material 102 or the optional second n-type substrate material 104.

As shown in FIG. 3E, after a desired number of epitaxial layers 106 are formed, the process includes merging the dopant regions 114 in the individual epitaxial layers 106 to form a p-type pillar 116. In one embodiment, merging the dopant regions 114 includes thermally diffusing the dopant regions 114 at a temperature (e.g., 1,100° C.) for a short period of time (e.g., 120 minutes). In other embodiments, merging the dopant regions 114 may include radiating the epitaxial layers 106 and/or via other suitable techniques.

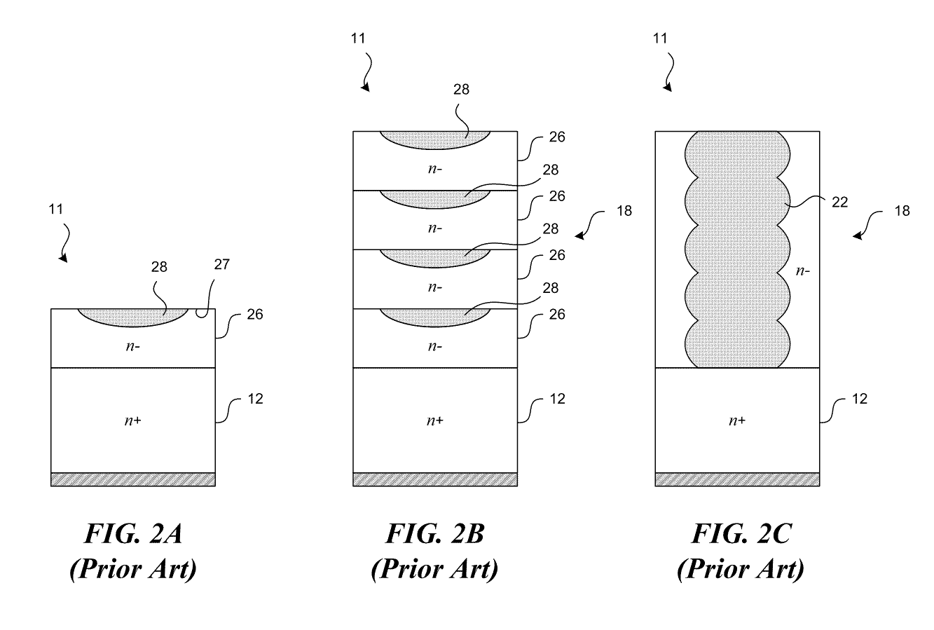

Several embodiments of the foregoing process can produce doped pillars with a reduced lateral dimension compared to the conventional technique discussed above with reference to FIGS. 2A-2C. Unlike the conventional technique, several embodiments of the foregoing process include forming a plurality of closely spaced or directly contacting dopant regions 114 vertically stacked in the individual epitaxial layers 106. As a result, short diffusion durations may be sufficient to merge the dopant regions 114, thus reducing lateral diffusion of the dopant in the epitaxial layers 106 in contrast to the conventional technique.

Several embodiments of the foregoing process can allow improved control of vertical and/or lateral doping concentrations and/or distribution profiles. For example, for each of the epitaxial layers 106, different dopant concentrations (e.g., increasing or decreasing with respect to the thickness H) and/or distribution profiles (e.g., a lateral and/or vertical dimension of the dopant regions 114) may be used for at least some of the dopant regions 114. As a result, the pillars 116 may have a select concentration and/or distribution profile after merging.

Even though the process is illustrated above as having the same openings 110 for patterning the individual epitaxial layers 106, in certain embodiments, other openings that are different in at least one of a location, a shape, a width, and a depth may be used for at least some of the epitaxial layers 106 to form pillars 116 with a conical shape as shown in FIGS. 3F or 3G. In other embodiments, other patterns of openings may be used for at least some of the epitaxial layers 106 to form pillars 116 with a stepped shape, a zigzag shape, a parabolic shape, and/or other suitable shapes.

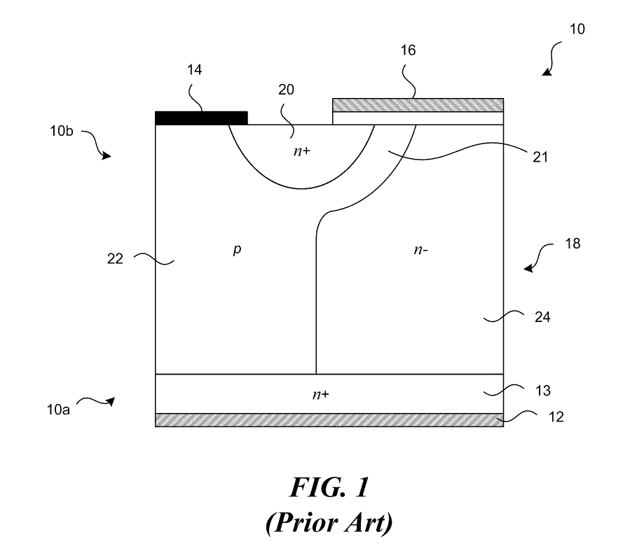

In further embodiments, the process may include additional operations prior to removing the photoresist 108. For example, an etching operation may be performed through the openings 110 to form a shallow recess (not shown) in the epitaxial layer 106. The shallow recess may be used for alignment of subsequent photo masks and/or other purposes. In yet further embodiments, the process can also include forming a source, a gate, a drain, and/or other suitable components to form a vertical MOSFET generally similar in structure to the MOSFET 10 in FIG. 1.

Simulations were performed based on a process generally similar to that discussed with reference to FIGS. 3A-3E. In these simulations, ten epitaxial layers were formed. Each of the epitaxial layers has a thickness of 4 microns and an n-type dopant concentration of 2.5×10¹⁵ atoms per centimeter cubed. Four boron doped regions were formed via a 4 micron wide photoresist opening in each of the epitaxial layers. The implantation energy and ion densities used are listed below:

| | Implantation energy | Ion density |
|---|---|---|
| | keV | atoms/cm² |
| First region | 200 | 5 × 10¹¹ |
| Second region | 1,000 | 5 × 10¹¹ |
| Third region | 1,700 | 5 × 10¹¹ |
| Fourth region | 2,500 | 5 × 10¹¹ |

After forming the four boron doped regions, thermal diffusion was performed at 1,100° C. for 120 minutes. The formed super junctions appeared to be generally uniform with an 8 micron pitch (i.e., a 4 micron boron pillar next to a 4 micron n-type pillar). After diffusion, the vertical extent of each implanted region is about 1 micron.

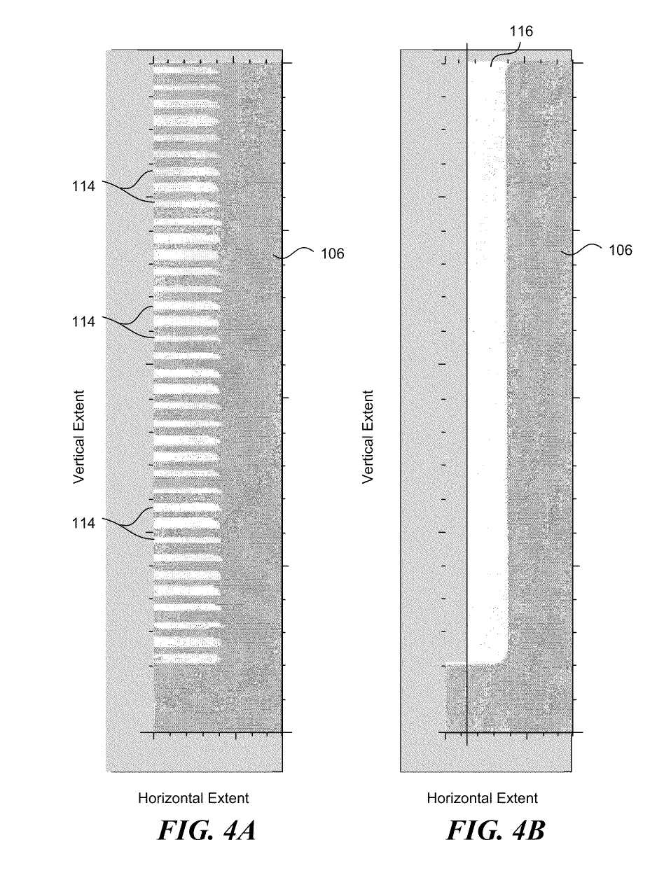

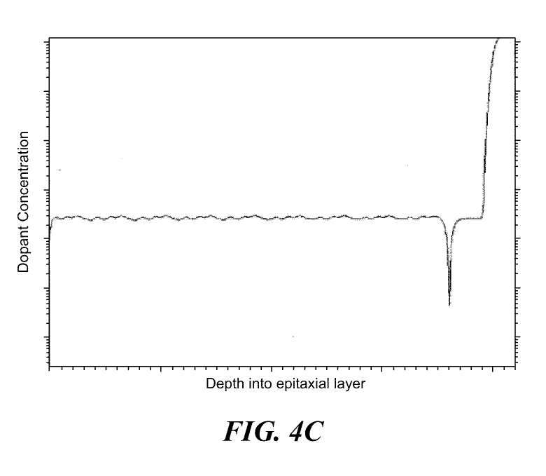

FIG. 4A illustrates an example of simulation results of the process in FIGS. 3A-3D. FIG. 4B illustrates simulation results of the process in FIG. 3E, and FIG. 4C is a plot of dopant concentration versus depth of the simulation results in FIG. 4B. In these simulations, boron is implanted at four different implantation energies into each of the ten n-type epitaxial layers 106, though other types of dopant and/or epitaxial layer may also be used. As shown in FIG. 4A, a plurality of dopant regions 114 are vertically stacked with a distance separating one another along a depth of the stacked epitaxial layers 106. As shown in FIG. 4B, after merging, the dopant regions 114 are diffused together to form a pillar or column 116 of boron dopant. The lateral extent of the column 116 is substantially the same as the lateral extent of the individual dopant regions 114, allowing the widths of the column 116 to be much narrower compared to prior art super junction devices.

As shown in FIG. 4C, the dopant concentration along the depth of the epitaxial layer 106 appears to be generally uniform. The individual implantation operations introduces a dopant region that has the highest doping concentration near a center of its vertical extent and decreasing doping concentrations toward two ends from the center. Because there is little lateral diffusion of the implanted dopant regions 114, the doping concentration is substantially constant across the width of the individual implanted dopant regions 114.

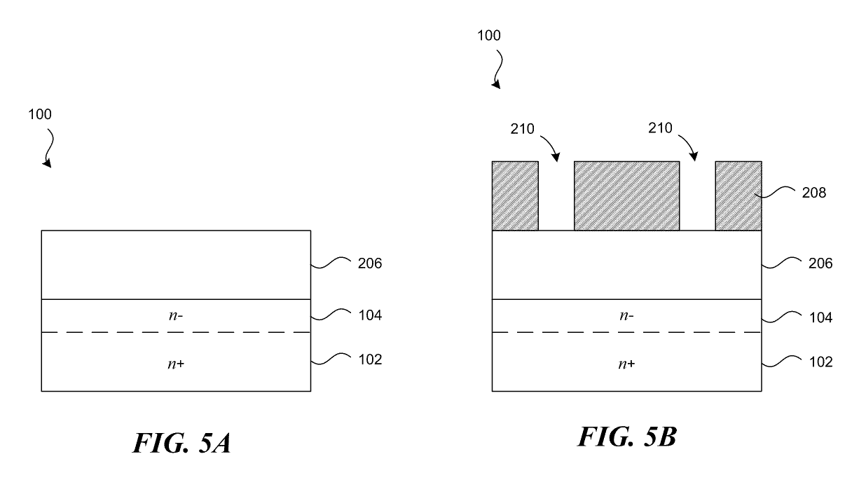

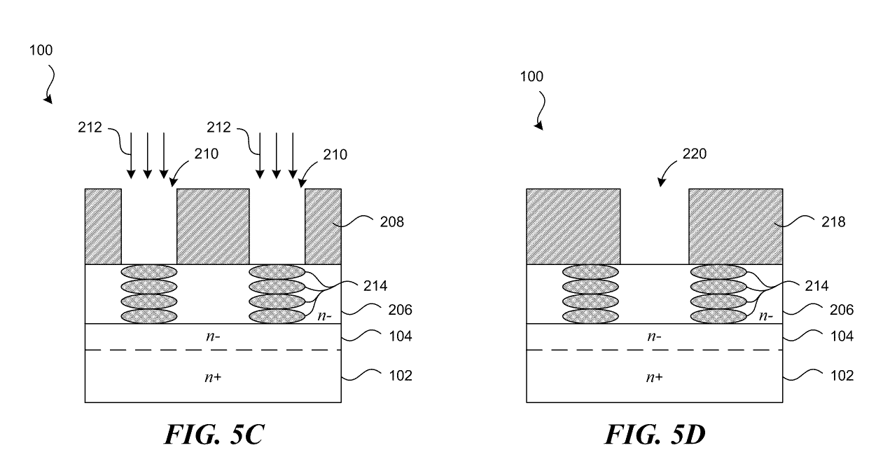

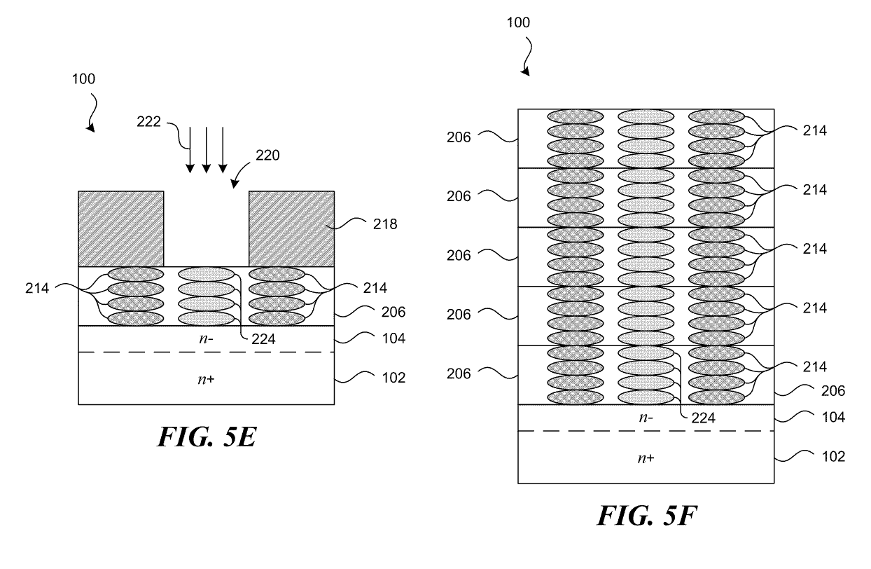

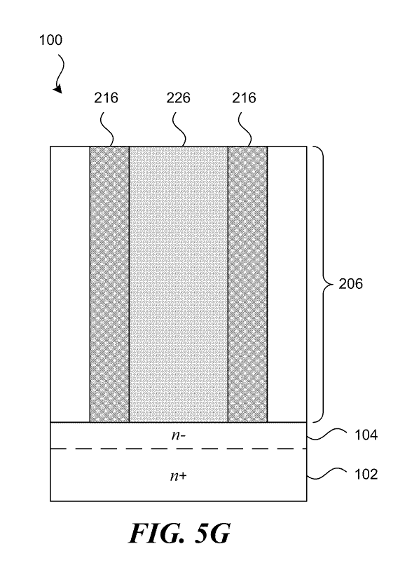

FIGS. 5A-5G are partially schematic cross-sectional views of a substrate 100 undergoing a process for forming a vertical MOSFET in accordance with additional embodiments of the technology. In the following discussion, several embodiments of the process may include components and/or structures that are generally similar to those discussed above with reference to FIGS. 3A-3G. As such, similar identification numbers refer to similar components and/or structures.

As shown in FIG. 5A, the process includes depositing an intrinsic (i.e., substantially non-doped) epitaxial layer 206 onto the optional second substrate material 104 via CVD, PECVD, ALD, and/or other suitable deposition techniques. After depositing the epitaxial layer 206, the process includes depositing a first photoresist 208 onto the epitaxial layer 206 via spin coating and/or other suitable techniques, as shown in FIG. 5B. The first photoresist 208 may then be patterned to form first openings 210. Even though two first openings 210 are shown in FIG. 5B, in other embodiments, the first photoresist 208 may include any desired number of first openings 210 based at least in part on a desired number of first pillars with a first dopant type.

As shown in FIG. 5C, the process includes implanting a plurality of vertically stacked first dopant regions 214 into the epitaxial layer 206 via the openings 210 with ions of the first dopant type (as indicated by the arrows 212). The first dopant type may be n-type or p-type. As shown in FIG. 5D, the process also includes removing the first photoresist 208 from the epitaxial layer 206 and depositing a second photoresist 218 onto the epitaxial layer 206. The second photoresist 218 may then be patterned to form a second opening 220. In the illustrated embodiment, the second opening 220 generally corresponds to a space between two adjacent columns of vertically stacked first dopant regions 214. In other embodiments, the second opening 220 may also correspond to a space that at least partially overlaps with at least one of the adjacent columns of vertically stacked first dopant regions 214.

As shown in FIG. 5E, the process includes implanting a plurality of vertically stacked second dopant regions 224 into the epitaxial layer 206 via the opening 220 with ions of a second dopant type (as indicated by arrows 222). The second dopant type is different than the first dopant type and may also be n-type or p-type depending on characteristics of the first dopant type. In the illustrated embodiment, the second dopant regions 224 are laterally spaced apart and between two adjacent columns of the first dopant regions 214. In other embodiments, the second dopant regions 224 may be laterally juxtaposed and in direct contact or may at least partially overlap with the two adjacent columns of the first dopant regions 214.

As shown in FIG. 5F, the process includes removing the second photoresist 218 and repeating the operations illustrated in FIGS. 5A-5E until a desired number of epitaxial layers 206 are formed. In the illustrated embodiment, five epitaxial layers 206 are shown for illustration purposes. In other embodiments, any desired number of epitaxial layers 206 may be formed.

As shown in FIG. 5G, after the desired number of epitaxial layers 206 are formed, the process includes merging the first dopant regions 214 and merging the second dopant regions 224 in the individual epitaxial layers 206 to form at least one first dopant-type (e.g., p-type) pillar 216 and at least one second dopant-type (e.g., n-type) pillar 226, respectively. In one embodiment, merging the first and second dopant regions 214 and 224 includes thermally diffusing the first and second dopant regions 214 and 224 at a temperature (e.g., 1,100° C.). In other embodiments, merging the first and second dopant regions 214 and 224 may include radiating the epitaxial layers 206 and/or other suitable techniques.

Several embodiments of the process discussed above with reference to FIGS. 5A-5G may have improved charge balance and control when compared to conventional techniques. In the conventional technique discussed above with reference to FIGS. 2A-2C, a p-type dopant is implanted in n-type epitaxial layers, in which the concentration and/or distribution profile of the n-type dopant may not be easily controlled. In contrast, several embodiments of the foregoing process implant particular types of dopant at a desired concentration and/or distribution profile and thus may have improved charge balance and control.

From the foregoing, it will be appreciated that specific embodiments of the technology have been described herein for purposes of illustration. However, various modifications may be made without deviating from the disclosure. Many of the elements of one embodiment may be combined with other embodiments in addition to or in lieu of the elements of the other embodiments. Accordingly, the disclosure is not limited except as by the appended claims.

I/we claim:

1. A method for forming a power device, comprising:
depositing an epitaxial layer on a substrate;
implanting a first dopant region in the epitaxial layer at a first depth;
implanting a second dopant region in the epitaxial layer at a second depth different than the first depth, the second dopant region being discrete from the first dopant region; and
merging the implanted first and second dopant regions into a continuous dopant column.

2. The method of claim 1 wherein:
depositing an epitaxial layer includes depositing an n-type epitaxial layer on an n-type substrate;
the method further includes:
depositing a photoresist onto the epitaxial layer;
patterning the deposited photoresist to form a mask opening;
implanting a first dopant region includes implanting via the mask opening boron with a first implantation energy;
implanting a second dopant region includes implanting via the mask opening boron with a second implantation energy lower than the first implantation energy;
the method further includes:
removing the photoresist after implanting the first and second dopant regions; and
repeating the epitaxial layer deposition, photoresist deposition and patterning, and first and second dopant region implantation operations until a desired number of epitaxial layers are formed; and
merging the implanted first and second dopant regions includes merging the implanted first and second dopant regions in each of the epitaxial layers after the desired number of epitaxial layers are formed via thermal diffusion.

3. The method of claim 1 wherein:
depositing an epitaxial layer includes depositing a first epitaxial layer on the substrate;
the method further includes:
depositing a first masking material onto the first epitaxial layer;
patterning the first masking material to form a first mask opening in the first masking material;
implanting a first dopant region includes implanting the first dopant region via the first opening in the first masking material;
implanting a second dopant region includes implanting the second dopant region via the first opening in the first masking material;
the method further includes:
removing the first masking material after implanting the first and second dopant regions;
depositing a second epitaxial layer on the first epitaxial layer;
depositing a second masking material onto the second epitaxial layer;
patterning the second masking material to form a second mask opening in the second masking material, the second mask opening generally corresponding to the first mask opening; and
implanting a third dopant region and a fourth dopant region in the second epitaxial layer via the second opening; and
merging the implanted first and second dopant regions includes merging the implanted first, second, third, and fourth dopant regions in the first and second epitaxial layers via thermal diffusion.

4. The method of claim 3 wherein the first and second mask openings are different in at least one of a location, a shape, and a width.

5. The method of claim 3 wherein the continuous dopant column has a lateral extent that is substantially the same as that of the first and second mask openings.

6. The method of claim 1 wherein:
implanting a first dopant region includes implanting the first dopant region with a first implantation energy;
implanting a second dopant region includes implanting the second dopant region with a second implantation energy; and
the method further includes adjusting the first and second implantation energy such that the first dopant region has a first depth and the second dopant region has a second depth different than the first depth.

7. The method of claim 1 wherein the first and second dopant regions are in direct contact with each other.

8. The method of claim 1 wherein the first and second dopant regions are vertically separated from each other by a portion of the epitaxial layer.

9. The method of claim 1 wherein:
the second depth is less than the first depth; and
the method further includes implanting a third dopant region at a third depth that is less than the second depth.

10. The method of claim 9 wherein the first, second, and third dopant regions together occupy substantially the entire depth of the epitaxial layer.

11. The method of claim 9 wherein:
the first and second dopant regions are vertically separated from each other by a first portion of the epitaxial layer;
the second and third dopant regions are vertically separated from each other by a second portion of the epitaxial layer, the first and second portions of the epitaxial layer having approximately the same vertical extent;
a third portion of the epitaxial layer extends beneath the first dopant region;
a forth portion of the epitaxial layer extends above the third dopant region, the individual third and forth portions of the epitaxial layer having a vertical extent that is approximately one half that of the first and second portions.

12. The method of claim 9, further comprising implanting a fourth dopant region at a fourth depth that is less than the third depth.

13. The method of claim 12 wherein:
first and second dopant regions are vertically separated from each other by a first portion of the epitaxial layer;
the second and third dopant regions are vertically separated from each other by a second portion of the epitaxial layer;
the third and fourth dopant regions are separated from each other by a third portion of the epitaxial layer;
a fourth portion of the epitaxial layer extends beneath the first dopant region;
a fifth portion of the epitaxial layer extends above the forth dopant region;
the first, second, and third portions of the epitaxial layer have approximately the same vertical extent; and
the individual fourth and fifth portions of the epitaxial layer have a vertical extent that is approximately one half that of the first, second, and third portions.

14. The method of claim 1 wherein the first and second dopant regions together occupy substantially the entire depth of the epitaxial layer.

15. The method of claim 1 wherein:
the first dopant region has a first dopant concentration; and
the second dopant region has a second dopant concentration different than the first dopant concentration.

16. A method for forming a vertical power device, comprising:
depositing a single epitaxial layer on a substrate;
sequentially implanting a plurality of dopant regions in the single epitaxial layer, the dopant regions being discrete from and vertical relative to one another; and
merging the sequentially implanted dopant regions into a continuous dopant column.

17. The method of claim 16 wherein:
sequentially implanting a plurality of dopant regions includes applying an implantation energy to implant the individual dopant regions via ion implantation; and
the method further includes controlling a depth of the individual dopant regions by adjusting the implantation energy.

18. The method of claim 16 wherein sequentially implanting a plurality of dopant regions includes:
applying a first implantation energy for a first duration;
removing the first implantation energy after the first duration expires; and
applying a second implantation energy for a second duration, the second implantation energy being different than the first implantation energy.

19. The method of claim 16 wherein sequentially implanting a plurality of dopant regions includes sequentially implanting a plurality of dopant regions individually containing at least one of boron (B), aluminum (Al), gallium (Ga), indium (In), and thallium (Ti).

20. The method of claim 16 wherein:
sequentially implanting a plurality of dopant regions includes sequentially implanting a first plurality of dopant regions individually containing at least one of boron (B), aluminum (Al), gallium (Ga), indium (In), and thallium (Ti);
the method further includes sequentially implanting a second plurality of dopant regions individually containing at least one of phosphorus (P), arsenic (As), and antimony (Sb); and
merging the sequentially implanted dopant regions includes:
merging the first dopant regions into a first dopant column; and
merging the second dopant regions into a second dopant column.

21. The method of claim 16 wherein:
sequentially implanting a plurality of dopant regions includes sequentially implanting a first plurality of dopant regions individually containing at least one of boron (B), aluminum (Al), gallium (Ga), indium (In), and thallium (Ti); and
the method further includes sequentially implanting a second plurality of dopant regions individually containing at least one of phosphorus (P), arsenic (As), and antimony (Sb); and
merging the sequentially implanted dopant regions includes:
merging the first dopant regions into a first dopant column; and
merging the second dopant regions into a second dopant column juxtaposed with the first dopant column.

22. The method of claim 16 wherein:
sequentially implanting a plurality of dopant regions includes sequentially implanting a first plurality of dopant regions individually containing at least one of boron (B), aluminum (Al), gallium (Ga), indium (In), and thallium (Ti); and
the method further includes sequentially implanting a second plurality of dopant regions individually containing at least one of phosphorus (P), arsenic (As), and antimony (Sb); and
merging the sequentially implanted dopant regions includes:
merging the first dopant regions into a first dopant column; and
merging the second dopant regions into a second dopant column juxtaposed and in direct contact with the first dopant column.

23. The method of claim 16 wherein:
sequentially implanting a plurality of dopant regions includes sequentially implanting a first plurality of dopant regions individually containing at least one of boron (B), aluminum (Al), gallium (Ga), indium (In), and thallium (Ti); and
the method further includes sequentially implanting a second plurality of dopant regions individually containing at least one of phosphorus (P), arsenic (As), and antimony (Sb); and
merging the sequentially implanted dopant regions includes:
merging the first dopant regions into a first dopant column; and
merging the second dopant regions into a second dopant column juxtaposed with but spaced apart from the first dopant column.

24. A method for forming a power device, comprising:
depositing an epitaxial layer on a substrate;
implanting a plurality of dopant regions in the epitaxial layer, the dopant regions being discrete from one another;
controlling a depth, a dopant concentration, and/or a distribution profile of the individual dopant regions by adjusting at least one of (1) an implantation energy, (2) an ion concentration, and (3) an implantation duration; and
merging the sequentially implanted dopant regions into a continuous dopant column.

25. The method of claim 24 wherein controlling a depth, a dopant concentration, and/or a distribution profile includes controlling a depth of the individual dopant regions by adjusting the implantation energy.

26. The method of claim 24 wherein controlling a depth, a dopant concentration, and/or a distribution profile includes controlling a dopant concentration of the individual dopant regions by adjusting the ion concentration and/or the implantation duration.

27. The method of claim 24 wherein controlling a depth, a dopant concentration, and/or a distribution profile includes controlling a distribution profile of the individual dopant regions by adjusting the implantation duration.

28. A vertical power device, comprising:
a drain at a first end;
a source and a gate at a second end opposite the first end along a first direction; and
a drift region between the drain at the first end and the source at the second end, the drift region including a p-type dopant column and an n-type dopant column juxtaposed with the p-type column, the p-type dopant column and the n-type dopant column together having a width in a second dimension generally perpendicular to the first direction, the width being less than 12 microns.

29. The power device of claim 28 wherein the drift region includes an intrinsic semiconductor material, and wherein the p-type dopant column and the n-type dopant column are located in the intrinsic semiconductor material.

30. The power device of claim 28 wherein the n-type dopant column comprises a plurality of epitaxial layers, the individual epitaxial layers having a thickness in the first direction, the thickness being greater than 3 microns and less than 5 microns.

31. The power device of claim 28 wherein the p-type dopant column comprises a plurality of implanted regions in each of the epitaxial layers, each implanted regions being located at a different depth in the epitaxial layer.

32. The power device of claim 31 wherein the individual implanted regions have a thickness in the first direction that is greater than 0.5 microns and less than 1.5 microns.

33. The power device of claim 31 wherein the individual implanted regions have a higher doping concentration near a center of a thickness of the individual implanted regions and a lower doping concentration near a top and a bottom of the thickness.

34. The power device of claim 33 wherein the higher doping concentration at the center is at most 10% higher than the lower doping concentration at the top and the bottom of the thickness.

35. The power device of claim 28 wherein a doping concentration of the p-type dopant column is substantially constant along the second direction.

36. The power device of claim 30 wherein the n-type dopant column has a first width in a first epitaxial layer and a second width in a second epitaxial layer, the first width being greater than the second width.

37. The power device of claim 30 wherein the n-type dopant column has a first width in a first epitaxial layer and a second width in a second epitaxial layer, the first width being less than the second width.
